(19) United States
(12) Patent Application Publication
(10) Pub. No.: US 2017/0263581 A1
(43) Pub. Date: Sep. 14, 2017

(54) ELECTRONIC DEVICE, PART MOUNTING BOARD, AND ELECTRONIC APPARATUS

(71) Applicant: SONY CORPORATION, TOKYO (JP)

(72) Inventors: KUNIHIKO SARUTA, TOKYO (JP); HIROSHI OZAKI, KANAGAWA (JP); HIDETOSHI KABASAWA, KANAGAWA (JP)

(21) Appl. No.: 15/506,286

(22) PCT Filed: Aug. 18, 2015
(86) PCT No.: PCT/JP2015/004085

§ 371 Date: Feb. 24, 2017

(30) Foreign Application Priority Data
Sep. 11, 2014 (JP) 2014-184813

(51) Int. Cl. H01L 23/00; H01L 23/498; B81B 7/00; H01L 23/31; H01L 25/065; H01L 27/146

(52) U.S. Cl. CPC H01L 24/14; H01L 25/0657; H01L 27/14634; B81B 7/0074; H01L 23/3157; H01L 23/49838; H01L 2225/06513; H01L 2224/1413; H01L 2224/14517; H01L 2924/3511

(57) ABSTRACT

[Object] To provide an electronic device, a part mounting board, and an electronic apparatus that are capable of preventing warpage of a board from occurring. [Solving Means] An electronic device according to an embodiment of the present technology includes a first circuit board and a second circuit board. The first circuit board includes a first main surface, a second main surface, and a plurality of external terminals. The plurality of external terminals include a first terminal group located at an outermost periphery of the first main surface, and are arranged on the first main surface in a matrix pattern. The second circuit board includes a terminal surface facing the second main surface, and a plurality of connection terminals. The plurality of connection terminals include a second terminal group that is arranged on the terminal surface and faces at least a part of the first terminal group, and are electrically connected to the second main surface.

### TECHNICAL FIELD

The present technology relates to a surface mounting type electronic device, and a part mounting board and an electronic apparatus that include the electronic device.

### BACKGROUND ART

The technology for mounting an electronic device has rapidly progressed, and various lamination/mounting technologies such as a chip-on-chip (COC) technology in which semiconductor chips are laminated and mounted have been developed.

The electronic device and the like using the lamination/mounting technology has, for example, a structure in which a circuit board and a semiconductor chip laminated thereon are connected to each other with soldering or the like. Further, in order to ensure the connection reliability, underfill resin is often filled between the semiconductor chip and the circuit board. In this case, because the thermal expansion coefficient of an underfill resin layer and the thermal expansion coefficient of a terminal differ, a large thermal stress is applied to the circuit board in thermal environment. As a result, warpage occurs in the circuit board in some cases. The warpage of the circuit board affects the reliability, device characteristics, and the like, which is a big problem to achieve the lamination/mounting.

In Patent Literature 1, a wiring board including dummy terminals is disclosed. The dummy terminals are arranged along diagonal lines of the board. Because a large stress is applied on the diagonal lines of the board, it triggers generation of warpage of the board. Therefore, when terminal electrodes are arranged on the diagonal lines of the board, poor connection of the terminal electrode may occur due to warpage of the board. In view of the above, in Patent Literature 1, the poor connection of the terminal electrode due to warpage of the board is prevented from occurring by arranging terminal electrodes so as to avoid the diagonal lines of the board and arranging dummy terminals on the diagonal lines.

Further, in Patent Literature 2, a supporting plate attached to a multilayer circuit wiring board is disclosed. The size of this supporting plate is smaller than that of the area of the multilayer circuit wiring board in which an electrode pad for secondary mounting is provided. In the case where the size of the supporting plate and the size of the area in which the electrode pad for secondary mounting is provided are the same, warpage occurs particularly on the outer periphery of the multilayer circuit wiring board. This is caused because the thermal expansion coefficient of a resin material that is the material of the multilayer circuit wiring board and the thermal expansion coefficient of metal that is the material of the supporting plate supporting this multilayer circuit wiring board differ. Poor connection may occur particularly in the electrode pad for secondary mounting placed on the outer periphery of the multilayer circuit wiring board due to the warpage of the multilayer circuit wiring board. In view of the above, in Patent Literature 2, the connection reliability is improved by forming the supporting plate having the size smaller than that of the area in which the electrode pad for secondary mounting is provided to avoid stress concentration on the outermost electrode pad for secondary mounting.

### CITATION LIST

### Patent Literature

Patent Literature 1: Japanese Patent No. 4082220

Patent Literature 2: Japanese Patent No. 4779619

### DISCLOSURE OF INVENTION

### Technical Problem

The performance of an electronic apparatus and the like to which an electronic device is applied has been increasingly improved, and the electronic apparatus has been multi-functionalized. In order to improve the reliability of the electronic device, it is desirable to prevent warpage of a board from occurring.

In view of the circumstances as described above, it is an object of the present technology to provide an electronic device, a part mounting board, and an electronic apparatus that are capable of preventing warpage of a board from occurring.

### Solution to Problem

An electronic device according to an embodiment of the present technology includes a first circuit board and a second circuit board.

The first circuit board includes a first main surface, a second main surface, and a plurality of external terminals.

The plurality of external terminals include a first terminal group located at an outermost periphery of the first main surface, and are arranged on the first main surface in a matrix pattern.

The second circuit board includes a terminal surface facing the second main surface, and a plurality of connection terminals. The plurality of connection terminals include a second terminal group that is arranged on the terminal surface and faces at least a part of the first terminal group, and are electrically connected to the second main surface.

In the electronic device, the plurality of external terminals and the plurality of connection terminals respectively include the first and second terminal groups that face each other at the outermost periphery. Accordingly, it is possible to reduce the bending stress that acts on the outer peripheral portion of the first circuit board at the time of thermal expansion or thermal contraction due to the temperature change. As a result, it is possible to prevent warpage of the board from occurring.

A part of at least one of the first terminal group and the second terminal group may include dummy terminals.

For example, it is sometimes difficult to arrange the first terminal group and the second terminal group so that they face each other from the viewpoint of the circuit design. In this case, when a part of at least one of the terminal groups includes dummy terminals, it is possible to cause the first terminal group and the second terminal group to face each other at desired positions.

When the first circuit board has a rectangular shape, the dummy terminals are typically arranged on four corners of at least one of the first main surface and the second main surface.

By arranging the dummy terminals on the four corners of the board to which a large bending stress is applied, it is possible to efficiently prevent warpage of the board from occurring.

The first circuit board may include an organic substrate or a semiconductor substrate. The semiconductor substrate may be an IC chip including an integrated circuit.

According to the electronic device, it is possible to prevent warpage at the time of temperature change from occurring regardless of the forming material and kind of the first circuit board.

the electronic device may further include an underfill resin layer formed between the second main surface and the terminal surface.

According to the above-mentioned configuration, it is possible to prevent warpage of the first circuit board due to the difference of the thermal expansion coefficient between the underfill resin layer and each terminal group from occurring while ensuring the bonding reliability of the first circuit board and the second circuit board.

The first circuit board may further include an insulating resin film. The insulating resin film is placed between the first main surface and the plurality of external terminals and is formed of a resin material that is softer than the plurality of external terminals.

Accordingly, it is possible to reduce the stress of the plurality of external terminals on the first main surface, and prevent warpage of the first circuit board from occurring.

The plurality of external terminals and the plurality of connection terminals may each include a projection electrode. The projection electrodes may be formed of different materials or the same material. In the case where the projection electrodes are formed of the same material, the thermal expansion coefficients of the projection electrodes can be made the same. Therefore, it is possible to prevent warpage of the first circuit board due to the difference between the thermal expansion coefficients from occurring.

The second circuit board does not necessarily need to include a single board, and may include a plurality of boards.

The second circuit board is not particularly limited, and may be an IC chip or a board including a sensor unit. The sensor unit may be, for example, an image sensor or an MEMS device.

According to the electronic device, it is possible to prevent warpage of the first circuit board from occurring. Therefore, it is possible to reliably ensure the device characteristics of the second circuit board.

A part mounting board according to an embodiment of the present technology includes a first circuit board, a second circuit board, and a third circuit board.

The first circuit board includes a first main surface, a second main surface, and a plurality of external terminals. The plurality of external terminals include a first terminal group located at an outermost periphery of the first main surface and arranged on the first main surface in a matrix pattern.

The second circuit board includes a terminal surface facing the second main surface, and a plurality of connection terminals. The plurality of connection terminals include a second terminal group that is arranged on the terminal surface and faces at least a part of the first terminal group, and are electrically connected to the second main surface.

The third circuit board is arranged so as to face the first main surface and electrically connected to the plurality of external terminals.

An electronic apparatus according to an embodiment of the present technology includes a first circuit board, a second circuit board, and a third board.

The first circuit board includes a first main surface, a second main surface, and a plurality of external terminals. The plurality of external terminals include a first terminal group located at an outermost periphery of the first main surface and arranged on the first main surface in a matrix pattern.

The second circuit board includes a terminal surface facing the second main surface, and a plurality of connection terminals. The plurality of connection terminals include a second terminal group that is arranged on the terminal surface and faces at least a part of the first terminal group, and are electrically connected to the second main surface.

The third circuit board is arranged so as to face the first main surface and electrically connected to the plurality of external terminals.

### ADVANTAGEOUS EFFECTS OF INVENTION

As described above, in accordance with the present technology, it is possible to prevent warpage of a board from occurring.

It should be noted that the effect described here is not necessarily limitative and may be any effect described in the present disclosure.

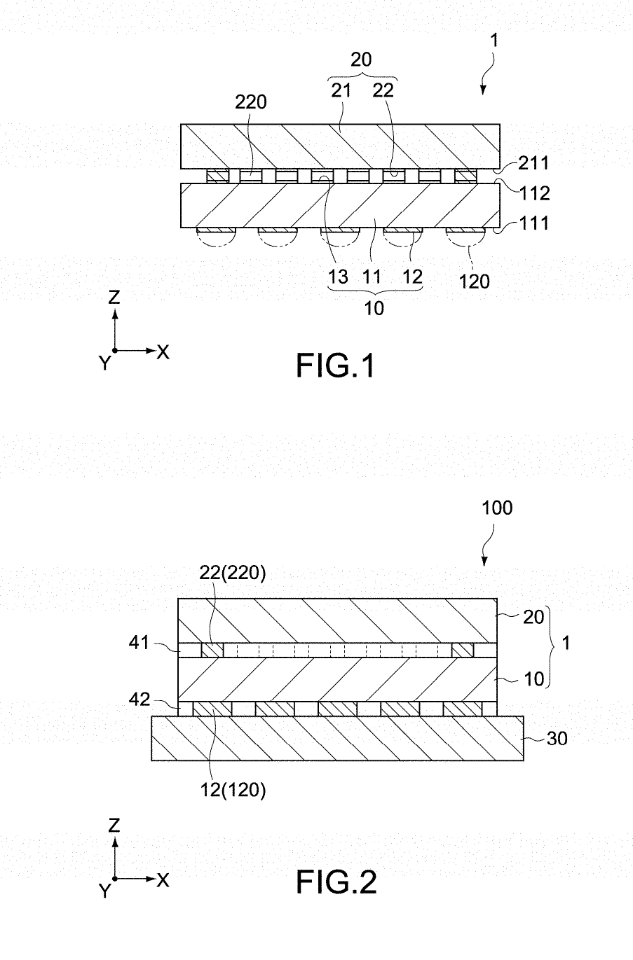

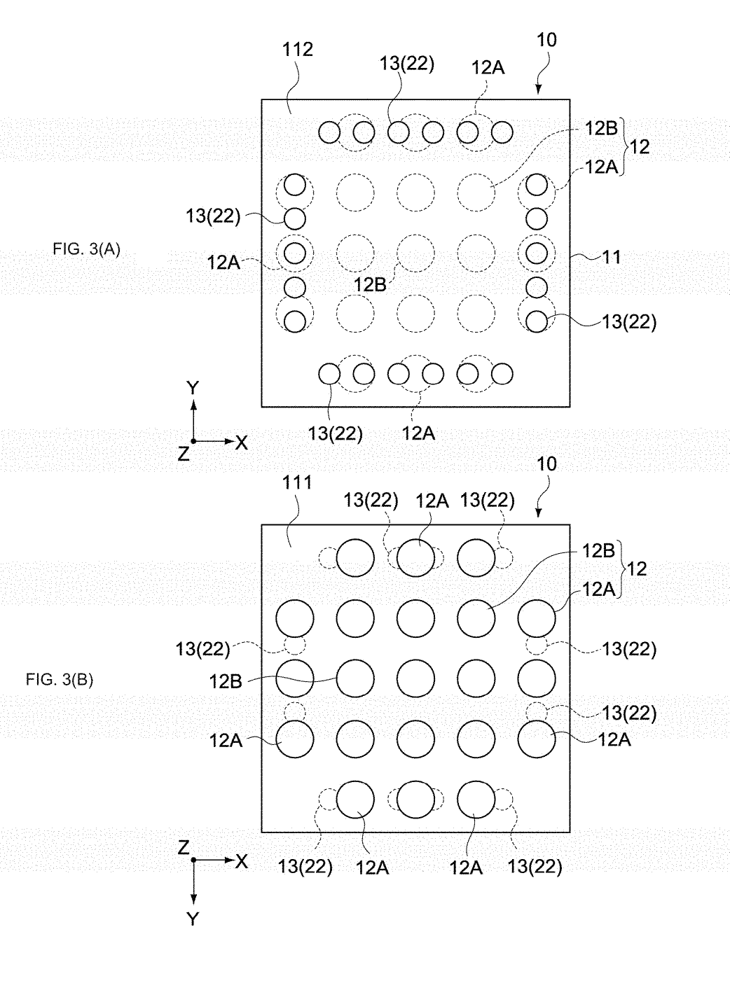

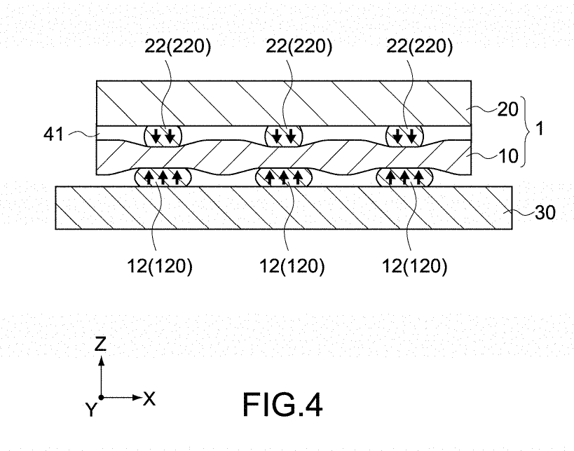

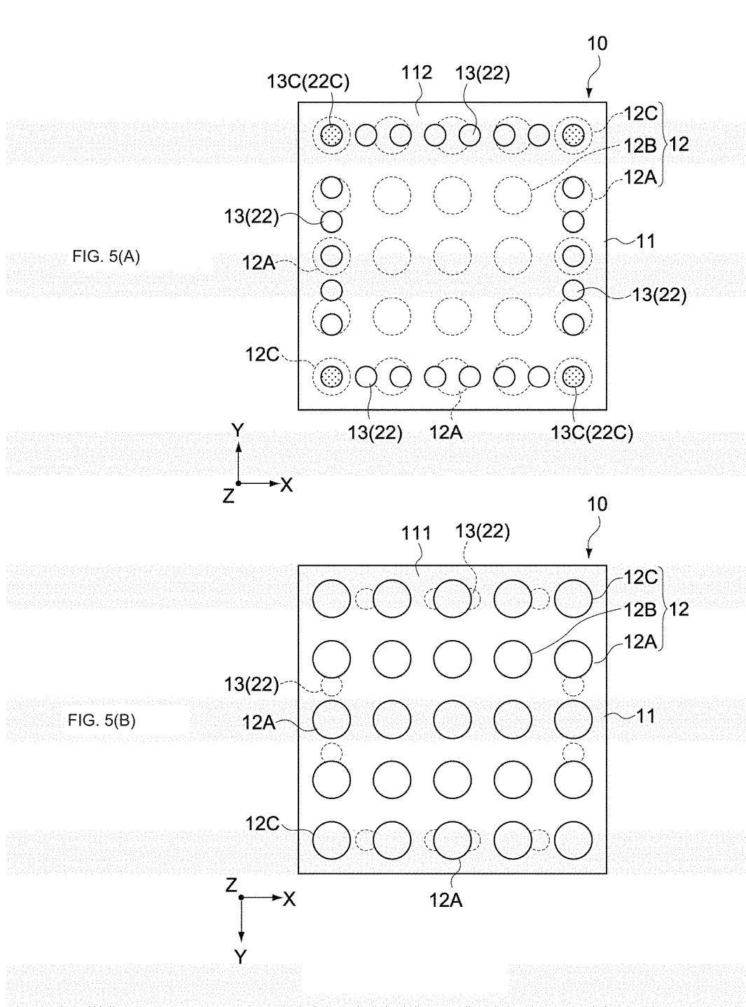

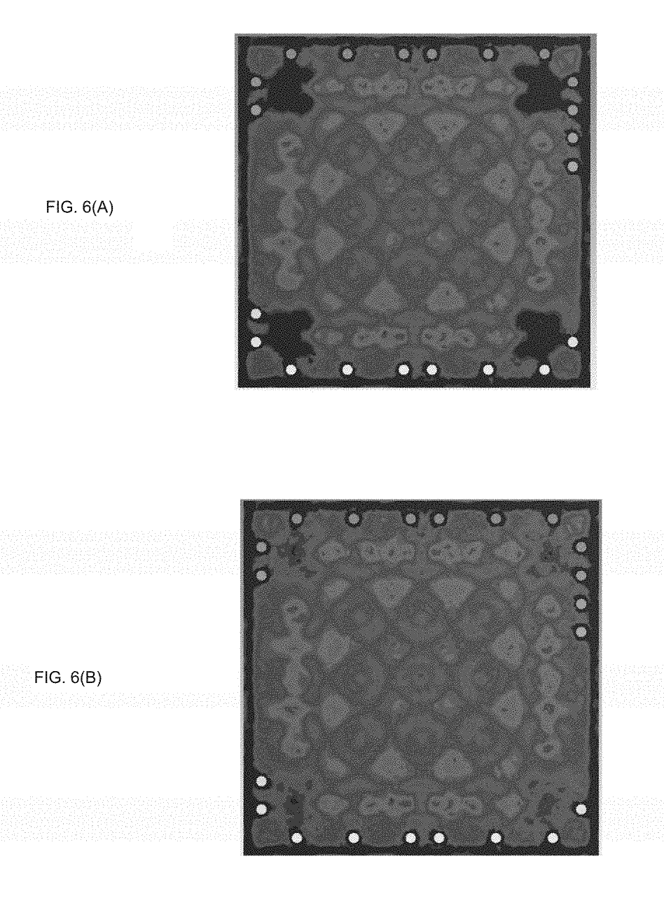

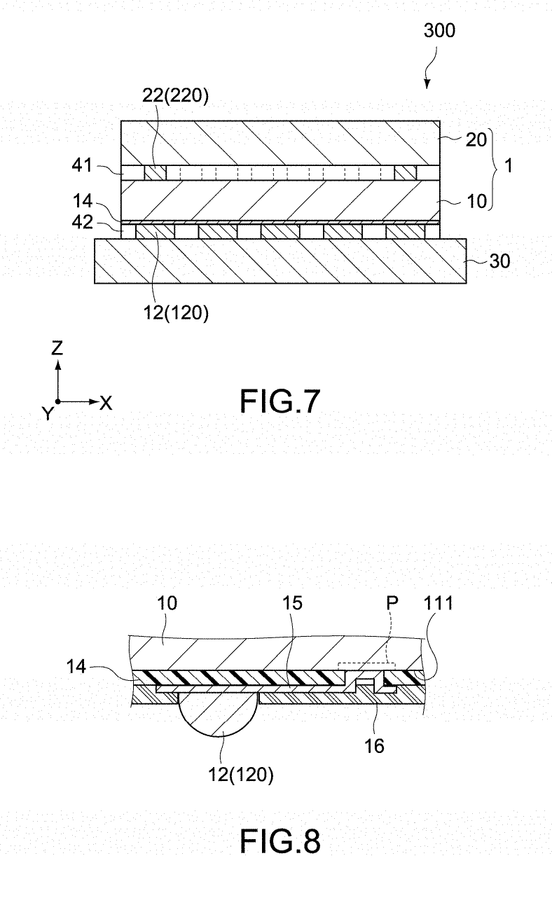

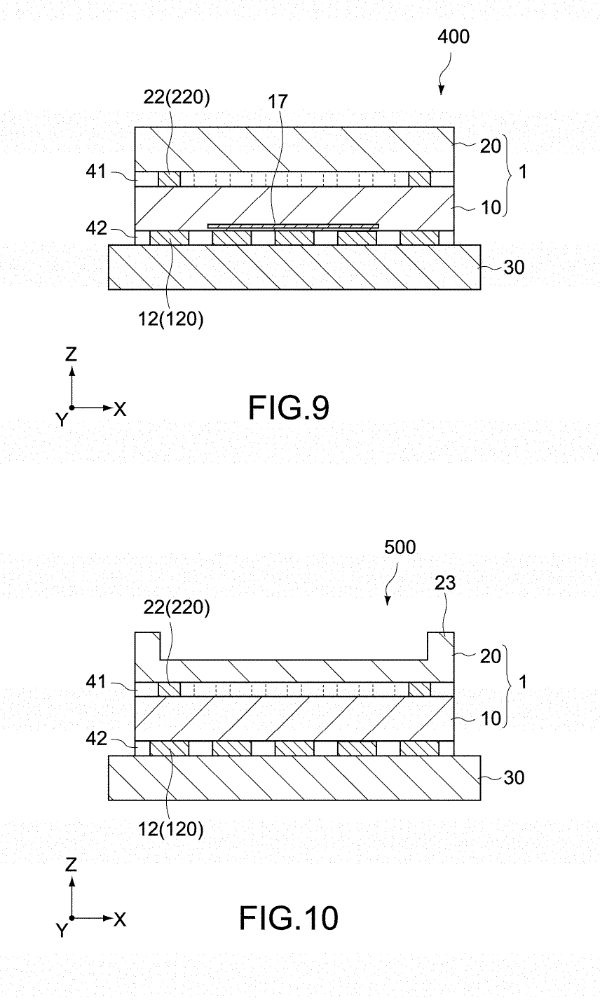

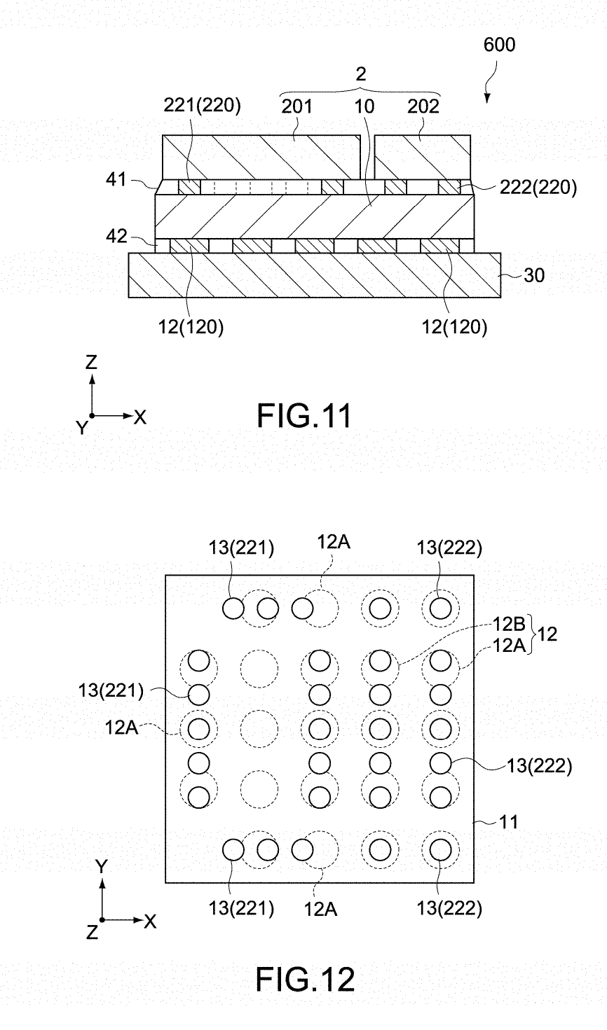

### BRIEF DESCRIPTION OF DRAWINGS

[FIG. 1] A cross-sectional view schematically showing the configuration of an electronic device according to a first embodiment of the present technology.

[FIG. 2] A schematic cross-sectional view of a part mounting board including the electronic device.

[FIG. 3] An example of the arrangement form of external terminals on a first circuit board in the electronic device, part A being a plan view of the first circuit board when viewed from a second main surface, part B being a plan view (rear view) of the first circuit board viewed from a first main surface.

[FIG. 4] A cross-sectional view schematically describing an operation of the electronic device.

[FIG. 5] A plan view and a rear view of a first circuit board constituting an electronic device according to a second embodiment of the present technology.

[FIG. 6] Simulation results representing in-plane distribution of a bending stress applied to the first circuit board due to a temperature change.

[FIG. 7] A schematic cross-sectional view of a part mounting board on which an electronic device according to a third embodiment of the present technology is mounted.

[FIG. 8] A main part enlarged cross-sectional view of the electronic device shown in FIG. 7.

[FIG. 9] A schematic cross-sectional view of a part mounting board on which an electronic device according to a fourth embodiment of the present technology is mounted.

[FIG. 10] A schematic cross-sectional view of a part mounting board on which an electronic device according to a fifth embodiment of the present technology is mounted.

[FIG. 11] A schematic cross-sectional view of a part mounting board on which an electronic device according to a sixth embodiment of the present technology is mounted.

[FIG. 12] A plan view of a first circuit board constituting the electronic device shown in FIG. 11.

### MODE(S) FOR CARRYING OUT THE INVENTION

Hereinafter, embodiments of the present technology will be described with reference to the drawings.

### First Embodiment

FIG. 1 is a cross-sectional view schematically showing the configuration of an electronic device 1 according to a first embodiment of the present technology. FIG. 2 is a schematic cross-sectional view of a part mounting board 100 including the electronic device 1.

In each figure, an X axis and Y axis represent plane directions perpendicular to each other, and a Z axis represents a height (thickness) direction perpendicular thereto (the same shall apply to the subsequent figures).

[Basic Configuration of Electronic Device]

As shown in FIG. 1, the electronic device 1 according to this embodiment includes a first circuit board 10 and a second circuit board 20. The electronic device 1 is configured as a single package part formed in a substantially parallelepiped shape as a whole. The second circuit board 20 is mounted on the first circuit board 10 by, for example, a flip-chip method.

The part mounting board 100 includes the electronic device 1 and a mounting board 30 (third circuit board). The electronic device 1 is mounted on the mounting board 30. In the illustrated example, the electronic device 1 is flip-chip mounted on the mounting board 30. However, it is not limited thereto, and the electronic device 1 may be mounted by a wire bonding method.

The part mounting board 100 is mounted on various electronic apparatuses such as a video camera, a game machine, and a portable information terminal. The mounting board 30 may be a single-sided board or double-sided board. On the mounting board 30, other many electric/electronic parts other than the electronic device 1 are mounted, which constitute at least a part of the control circuit of the electronic apparatus.

Next, details of the first and second circuit boards 10 and 20 constituting the electronic device 1 will be described.

The first circuit board 10 includes a board body 11 and a plurality of external terminals 12. The board body 11 has a first main surface 111 and a second main surface 112. The plurality of external terminals 12 are arranged on the first main surface 111. On the second main surface 112, a plurality of pad portions 13 electrically connected to the second circuit board 20 are provided.

In this embodiment, the plane shape of the first circuit board 10 is a square shape. However, it is not limited thereto, and the plane shape of the first circuit board 10 may be a rectangular shape or another polygonal shape. Also the thickness is not particularly limited, and it is 100 pm to 150 pm, for example. The first circuit board 10 is typically formed of a wiring board, a semiconductor bare chip (IC chip), or the like.

As the wiring board, a resin board, a metal board, a ceramic board, and the like can be applied. In this case, the board body 11 is formed of, for example, a synthetic resin material, a metal material, or a ceramic material, and a wiring material therein. On the other hand, in the case where the first circuit board 10 is formed of a semiconductor bare chip, the board body 11 is formed of a semiconductor substrate such as a silicon substrate and a gallium-arsenic substrate. On the semiconductor substrate, an integrated circuit including a transistor, a memory, and the like, a via passing through the front and the back of the semiconductor substrate, and the like, are formed. The first circuit board 10 may include a control circuit that controls driving of the second circuit board 20 therein.

The first main surface 111 forms one main surface (lower surface in FIG. 1) of the board body 11, and the second main surface 112 forms a main surface (upper surface in FIG. 1) opposite to the first main surface 111. The area of the first and second main surfaces 111 and 112, which excludes the area in which external terminals 12 and pad portions 13 are formed, is typically covered with an electric insulation protection film formed of a silicon oxide film, a silicon nitride film, or the like.

The plurality of external terminals 12 and the plurality of pad portions 13 are each formed of a conductor layer that is laminated on the main surfaces 111 and 112 of the board body 11 and has a predetermined shape. The conductor material forming the external terminals 12 and the pad portions 13 is not particularly limited. The external terminals 12 and the pad portions 13 may be formed of a metal single-layer film formed of Cu, Al, or the like, or a lamination film formed of different metals such as Au/Ti/Ni.

The plurality of external terminals 12 may each include a projection electrode 120 electrically/mechanically connected to a land portion (or pad portion) formed on the surface of the mounting board 30. The projection electrode 120 is formed of a solder bump (ball bump) provided to the respective plurality of external terminals 12. Other than that, it may be formed of a plating bump, a gold bump, or the like.

On the joining portion between the first circuit board 10 and the mounting board 30, an underfill resin layer 42 may be formed as shown in FIG. 2. Accordingly, it is possible to ensure the reliability of the joining portion because the mechanical strength of the joining portion is improved. The underfill resin layer 42 is typically formed of a heat-curable resin material such as epoxy-based resin, and may contain an appropriate filler as necessary.

The plurality of pad portions 13 are arranged corresponding to a plurality of connection terminals 22 arranged on a terminal surface 211 of the second circuit board 20. The number of pad portions 13 may be the same as or different from the number of external terminals 12. The external terminals 12 and the pad portions 13 are electrically connected to each other via the inside of the board body 11. The external terminals 12 typically have a function of rearranging the layout of the pad portions 13 on the first main surface 111.

The second circuit board 20 includes a board body 21 and the plurality of connection terminals 22. The board body 21 has the terminal surface 211 facing the first circuit board 10 (second main surface 112), and the plurality of connection terminals 22 are arranged on the terminal surface 211.

In this embodiment, the plane shape of the second circuit board 20 is formed in a square shape similarly to the first circuit board 10. However, it is not limited thereto, and the plane shape of the second circuit board 10 may be a rectangular shape or another polygonal shape. Further, in this embodiment, the second circuit board 20 is formed to have the same size as that of the first circuit board 10. However, it is not limited thereto, and the second circuit board 20 may be formed to have a size smaller (or larger) than that of the first circuit board 10.

The second circuit board 20 typically includes a wiring board, an IC chip, a sensor device, and the like. Specifically, the second circuit board 20 is formed of a bare chip having an integrated circuit formed on the surface thereof, or includes an imaging device having CCD (Charge Coupled Device)/CMOS (Complementary Metal Oxide Semiconductor) imager or the like therein, and a sensor unit such as an angular velocity sensor prepared by using a MEMS (Micro Electro Mechanical System) technology. The board body 21 may be formed of a single-layer silicon substrate, or a composite substrate such as an SOI (Silicon On Insulator) substrate.

The plurality of connection terminals 22 are arranged along the peripheral edge (four sides) of the board body 21 in a single row. The plurality of connection terminals 22 are each formed of a conductor layer that is laminated on the terminal surface 211 of the board body 21 and has a predetermined shape. The conductor material forming the connection terminals 22 is not particularly limited. The connection terminals 22 may be formed of a metal single-layer film formed of Cu, Al, or the like, or a lamination film formed of different metals such as Au/Ti/Ni.

The plurality of connection terminals 22 may each include a projection electrode 220 electrically/mechanically connected to the respective pad portions 13 of the first circuit board 10. The projection electrode 220 is formed of a solder bump (ball bump) provided to the respective plurality of connection terminals 22. Other than that, it may be formed of a plating bump, a gold bump, or the like. In this embodiment, the projection electrode 220 is formed of a solder material that is the same as or similar to that of the projection electrode 120 constituting the external terminals 12. However, it goes without saying that it is not limited thereto.

Between the first circuit board 10 (second main surface 112) and the second circuit board 20 (terminal surface 211), an underfill resin layer 41 may be formed as shown in FIG. 2. Accordingly, it is possible to ensure the reliability of the joining portion because the mechanical strength of the joining portion is improved. The underfill resin layer 41 is typically formed of a heat-curable resin material such as epoxy-based resin, and may contain an appropriate filler as necessary.

Next, the arrangement form of the external terminals 12 and the connection terminals 22 will be described.

Part A and part B of FIG. 3 each show an example of the arrangement form of the external terminals 12 and the pad portions 13 on the first circuit board 10. Part A is a plan view of the first circuit board 10 when viewed from the second main surface 112, and part B is a plan view (rear view) of the first circuit board 10 when viewed from the first main surface 111.

Note that although the external terminals 12 and the pad portions 13 (connection terminals 22) are presented in a circular shape in each view, the actual shape is not limited thereto and may be a rectangular shape or the like.

The plurality of external terminals 12 are arranged on the first main surface 111 in a matrix pattern. The external terminals 12 include a terminal group 12A (first terminal group) located at the outermost periphery of the first main surface 111 and a terminal group 12B located to be closer to the inside (central side) of the board than the terminal group 12A. The terminal group 12A is linearly arranged along the peripheral edge (four sides) of the board body 11.

On the other hand, as shown in part A and part B of FIG. 3, the plurality of pad portions 13 are arranged corresponding to the plurality of connection terminals 22 of the second circuit board 20 along the peripheral edge (four sides) of the board body 11 in a single raw. The plurality of pad portions 13 are typically arranged at a pitch narrower than that of the external terminals 12. The size of the pad portions 13 is not particularly limited, and may be smaller than that of the external terminals 12 as shown in the figure or the same as that of the external terminals 12.

In this embodiment, the plurality of pad portions 13, i.e., the plurality of connection terminals 22 corresponding thereto, constitute a terminal group (second terminal group) that faces the terminal group 12A (in a Z-axis direction) with the board body 11 disposed therebetween.

The plurality of connection terminals 22 (pad portions 13) do not necessarily need to face all of the external terminals 12 included in the terminal group 12A, and only have to be arranged so as to face at least a part of the external terminals 12 included in the terminal group 12A. In this embodiment, the plurality of connection terminals 22 are arranged so as to face all of the external terminals 12 included in the terminal group 12A. However, it is not limited thereto, and the plurality of connection terminals 22 may be arranged so as to face the external terminals 12 located on three sides of the board body 11 or two opposed sides of the board body 11 in the plurality of external terminals 12 included in the terminal group 12A.

[Operation of Electronic Device]

The electronic device 1 according to this embodiment configured as described above constitutes the part mounting board 100 by being flip-chip mounted on the mounting board 30 as shown in FIG. 2. For mounting the electronic device 1 on the mounting board 30, a reflow furnace is typically used.

In the reflow furnace, preliminary solder (not shown) applied to the land portion of the mounting board 30 and a part of the projection electrode 120 are remelted by heating the electronic device 1 and the mounting board 30 to a predetermined temperature to bond the external terminals 12 on the mounting board 30. At this time, a stress is generated on the board body 11 due to the difference between thermal expansion coefficients of the board body 11 of the first circuit board 10, the external terminals 12 (projection electrode 120), the connection terminals 22 (projection electrode 220), the underfill resin layer 41, and the like, as schematically shown in FIG. 4.

Note that in the case where the external terminals 12 and the connection terminals 22 located at the respective peripheral portions of the main surfaces 111 and 112 of the first circuit board 10 are arranged to be displaced, a large bending stress is generated in the vicinity of the peripheral portion due to the difference between the pressing positions from the external terminals 12 and the connection terminals 22. This bending stress causes warpage to occur particularly on the outer periphery of the first circuit board 10. This warpage affects the device characteristics of the electronic device 1 or causes poor connection with the mounting board 30 to occur.

On the other hand, in this embodiment, the external terminals 12 (terminal group 12A) and the connection terminals 22 located at the respective peripheral portions of the main surfaces 111 and 112 of the first circuit board 10 are arranged so as to face each other in the Z-axis direction with the board body 11 disposed therebetween, as described above. Therefore, the pressing positions of the external terminals 12 (terminal group 12A) and the connection terminals 22 on the board body 11 overlap with each other. As a result, a bending stress on the outer peripheral portion of the board body 11 is relaxed. Specifically, because the stress is balanced so that the pressing forces from the terminals are balanced on the upper and lower sides of the board body 11, the bending stress on the outer peripheral portion of the first circuit board 10 is reduced. As a result, deformation of the board is less likely to occur.

As described above, according to this embodiment, it is possible to mount the electronic device 1 on the mounting board 30 without causing warpage to occur on the first circuit board 10. In particular, it is possible to achieve significant effects in the case where the thickness of the first circuit board 10 is thin, e.g., 100 pm to 150 pm. Accordingly, it is possible to properly mount the electronic device 1 on the mounting board 30 while ensuring the device characteristics of the electronic device 1. Further, it is possible to provide the part mounting board 100 having excellent device characteristics and bonding reliability or an electronic apparatus on which the part mounting board 100 is mounted.

Further, because the projection electrodes 120 and 220 provided to the external terminals 12 and the connection terminals 22 are formed of the same kind of solder material, the thermal expansion coefficients of the projection electrodes 120 and 220 are the same. Accordingly, it is possible to prevent the warpage of the first circuit board 10 from occurring without depending on the temperature change amount.

Further, according to this embodiment, it is possible to ensure desired reliability of the electronic device 1 also with respect to the temperature change in the electronic apparatus having the part mounting board 100 therein. That is, even if thermal expansion (or thermal contraction) of the electronic device 1 occurs due to the temperature change in the inside of the electronic apparatus, it is possible to prevent the device characteristics of the electronic device 1 from deteriorating because it is possible to prevent warpage from occurring due to a bending stress of the first circuit board 10.

### Second Embodiment

Part A and part B of FIG. 5 are respectively a plan view and a rear view of the first circuit board 10 constituting an electronic device according to a second embodiment of the present technology. Hereinafter, configurations different from those according to the first embodiment will be mainly described, the same configurations as those according to the above-mentioned embodiment will be denoted by the same reference numerals, and a description thereof will be omitted or simplified.

In the electronic device, a certain number of the plurality of external terminals 12 of the first circuit board 10 and a certain number of the plurality of connection terminals 22 of the second circuit board 20 are necessary to transmit/receive an electric signal between the boards 10 and 20. Further, not only the number of terminals 11 and 22 but also the size, arrangement, and the like are changed depending on the designing or processing. Therefore, in some cases, it is difficult to make the positions of the terminals located on the outer periphery of both main surfaces of the first circuit board 10 overlap with each other. In this case, by arranging dummy pads on one or both of the main surfaces of the first circuit board 10, it is possible to make the pad positions on the outer peripheral portion of the board face each other. The dummy pads are actually not electrically connected.

As shown in part A and part B of FIG. 5, in this embodiment, dummy terminals 12C as a part of the external terminals 12 are arranged on the four corners of the first main surface 101, and dummy pads 13C as a part of the pad portions 13 are arranged on the four corners of the second main surface 102. The dummy terminals 12C constitute a part of the terminal group 12A (first terminal group) located at the outermost periphery of the plurality of external terminals 12.

On the other hand, on the terminal surface 211 of the second circuit board 20, dummy terminals 22C connected to the dummy pads 13C are arranged as a part of the connection terminals 22. The dummy terminals 22C constitute a part of the terminal group (second terminal group) that faces the terminal group 12A in the Z-axis direction with the board body 11 disposed therebetween.

Accordingly, it is possible to make the external terminals 12 and the connection terminals 22 overlap (face) with each other at the positions of the four corners of the first circuit board 10.

Part A of FIG. 6 shows in-plane distribution of a bending stress applied to the first circuit board 10 due to the temperature change in the case where the dummy terminals 12C and 22C are not arranged. The color shades represent the magnitude of the bending stress. Specifically, on the position with a deep color on the four corners of the first circuit board 10, a large bending stress is applied. On the other hand, part B of FIG. 6 shows in-plane distribution of a bending stress applied to the first circuit board 10 due to the temperature change in the case where the dummy terminals 12C and 22C are arranged. It can be seen that the magnitude of the bending stress applied on the four corners of the first circuit board 10 is reduced as compared with part A of FIG. 6.

As described above, according to this embodiment, it is possible to reduce the bending stress on the four corners of the first circuit board 10 because the dummy terminals 12C and 22C facing each other are arranged on the four corners of the first circuit board 10. Accordingly, it is possible to effectively prevent the warpage of the first circuit board 10 from occurring.

Typically, the dummy terminals 12C are formed with the same material as that of the external terminals 12 (12A and 12B) and in the same size and shape as those of the external terminals 12 (12A and 12B). Also the dummy terminals 22C (pad portions 13C) are formed with the same material as that of the connection terminals 22 (pad portions 13) and in the same size and shape as those of the connection terminals 22 (pad portions 13), similarly. Further, the positions or number of the dummy terminals 12C and 22C are not limited to those described in the above example, and the dummy terminals 12C and 22C may be arranged at other arbitrary positions. Also in this case, both of the dummy terminals 12C and 22C do not necessarily need to be arranged, and only one of them may be arranged.

### Third Embodiment

FIG. 7 is a schematic cross-sectional view of a part mounting board 300 on which an electronic device according to a third embodiment of the present technology is mounted. FIG. 8 is a main part enlarged cross-sectional view of the electronic device. Hereinafter, configurations different from those according to the first embodiment will be mainly described, the same configurations as those according to the above-mentioned embodiments will be denoted by the same reference numerals, and a description thereof will be omitted or simplified.

In order to ensure the bonding reliability of the electronic device 1 and the mounting board 30, the underfill resin layer 42 may be provided to the joining portion between the electronic device 1 and the mounting board 30. In this case, because the thermal expansion coefficient of underfill resin is larger than that of the external terminals 12 (projection electrode 120) in most cases, the underfill resin strongly contracts at low temperature, and the plurality of external terminals 12 give a relatively strong stress on the first circuit board 10, which may trigger generation of warpage of the first circuit board 10.

In this regard, in this embodiment, the first circuit board 10 further includes a resin film 14 provided between the first main surface 111 and the plurality of external terminals 12. As shown in FIG. 8, in the first circuit board 10, a wiring layer 15 for rewiring is formed on the first main surface 111. The wiring layer 15 electrically connects a pad portion P with the external terminal 12 located at a position different from that of the pad portion P. The resin film 14 is formed between the first main surface 111 and the wiring layer 15. Note that the external terminals 12 (projection electrodes 120) are provided to the opening portion of a protection film 16 that protects the wiring layer 15.

The resin film 14 is formed of an electric insulation resin material that is softer than the external terminals 12. Typically, the resin film 14 is formed of a material having a low Young's modulus such as polyimide. Accordingly, because the stress applied from the external terminals 12 on the first main surface 111 can be reduced, it is possible to reduce the warpage of the first circuit board 10.

### Fourth Embodiment

FIG. 9 is a schematic cross-sectional view of a part mounting board 400 on which an electronic device according to a fourth embodiment of the present technology is mounted. Hereinafter, configurations different from those according to the first embodiment will be mainly described, the same configurations as those according to the above-mentioned embodiments will be denoted by the same reference numerals, and a description thereof will be omitted or simplified.

In the part mounting board 400 according to this embodiment, the first circuit board 10 is formed of a semiconductor chip including an integrated circuit 17. The integrated circuit 17 is typically formed of the surface of a silicon substrate.

In the case where an IC is prepared on the board, the device characteristics may be significantly changed when large warpage occurs on the board because the carrier mobility of the transistor of the IC is changed by the stress.

In this embodiment, because the plurality of external terminals 12 and the connection terminals 22 face each other at the peripheral edge positions of the first circuit board 10 similarly to the above-mentioned first embodiment, a bending stress that acts on the first circuit board 10 due to the temperature change is reduced. Accordingly, because warpage of the first circuit board 10 is reduced, it is possible to suppress the change in the device characteristics of the transistor constituting the integrated circuit 17 and the like. The integrated circuit 17 may be formed on the surface (first main surface) on which the external terminals 12 are arranged as shown in the figure, or on the surface (second main surface) on which the connection terminals 22 are arranged.

### Fifth Embodiment

FIG. 10 is a schematic cross-sectional view of a part mounting board 500 on which an electronic device according to a fifth embodiment of the present technology is mounted. Hereinafter, configurations different from those according to the first embodiment will be mainly described, the same configurations as those according to the above-mentioned embodiments will be denoted by the same reference numerals, and a description thereof will be omitted or simplified.

The part mounting board 500 according to this embodiment includes a reinforcing portion 23 formed in a frame shape on the upper surface of the second circuit board 20. The reinforcing portion 23 is formed along the peripheral edge of the second circuit board 20. Accordingly, the rigidity of the second circuit board 20 with respect to the bending stress is improved, and it is possible to prevent warpage not only on the first circuit board 10 but also on the second circuit board 20 from occurring.

The reinforcing portion 23 may be typically formed by processing an active layer of an SOI board constituting the second circuit board 20 in a predetermined shape. On the active layer, a MEMS mechanism unit such as an actuator unit and a sensor unit is provided and the reinforcing portion 23 can be formed as a frame portion that supports the MEMS mechanism unit.

### Sixth Embodiment

FIG. 11 is a schematic cross-sectional view of a part mounting board 600 on which an electronic device 2 according to a sixth embodiment of the present technology is mounted. FIG. 12 is a plan view of the first circuit board 10 constituting the electronic device 2. Hereinafter, configurations different from those according to the first embodiment will be mainly described, the same configurations as those according to the above-mentioned embodiments will be denoted by the same reference numerals, and a description thereof will be omitted or simplified.

In the part mounting board 600 according to this embodiment, the second circuit board of the electronic device 2 includes a plurality of circuit boards. In this embodiment, the second circuit board includes two circuit boards 201 and 202. The two circuit boards 201 and 202 are laminated on the first circuit board 10 (second main surface) to be adjacent to each other.

On the terminal surfaces of the second circuit boards 201 and 202, a plurality of connection terminals 222 and 222 connected to the plurality of pad portions 13 on the first circuit board 10 are respectively arranged. The plurality of connection terminals 221 and 222 are arranged along the vicinity of the respective circuit boards 201 and 202 in a single raw. A part of the connection terminals 221 and 222 constitutes a terminal group (second terminal group) that faces a part of the terminal group 12A located on the outermost periphery in the plurality of external terminals 12, as shown in FIG. 12. Note that the remaining part of the connection terminals 221 and 222 is arranged so as to face a part of the terminal group 12B located to be closer to the inside than the terminal group 12A.

In the electronic device 2 and the part mounting board 600 according to this embodiment configured as described above, the connection terminals 221 and 222 of the circuit boards 201 and 202 are arranged so as to face the external terminals 12 located at the outermost periphery. Therefore, similarly to the first embodiment, a bending stress that acts on the first circuit board 10 due to the temperature change is reduced. Accordingly, it is possible to reduce the warpage of the first circuit board 10.

Although embodiments of the present technology have been described, the embodiments of the present technology are not limited to the above-mentioned embodiments and various modifications can be made without departing from the essence of the present technology.

For example, although a laminated structure of two circuit boards has been described as an example of the electronic device in the above-mentioned embodiments, the present technology can be applied also to the electronic device having a stack structure in which three or more circuit boards (e.g., IC chip) are laminated.

Further, the above-mentioned embodiments do not necessarily need to be separately implemented, and a plurality of embodiments may be implemented at the same time. For example, the dummy terminal described in the second embodiment can be applied to another embodiment similarly.

It should be noted that the present technology may take the following configurations.

(1) An electronic device, including:

a first circuit board that includes a first main surface, a second main surface, and a plurality of external terminals arranged on the first main surface in a matrix pattern, the plurality of external terminals including a first terminal group located at an outermost periphery of the first main surface; and

a second circuit board that includes a terminal surface facing the second main surface, and a plurality of connection terminals electrically connected to the second main surface, the plurality of connection terminals including a second terminal group that is arranged on the terminal surface and faces at least a part of the first terminal group.

(2) The electronic device according to (1) above, in which a part of at least one of the first terminal group and the second terminal group includes dummy terminals.

(3) The electronic device according to (2) above, in which

the first circuit board has a rectangular shape, and

the dummy terminals are arranged on four corners of at least one of the first main surface and the second main surface.

(4) The electronic device according to any one of (1) to (4) above, in which

the first circuit board includes a semiconductor substrate.

(5) The electronic device according to (4), in which

the semiconductor substrate includes an integrated circuit.

(6) The electronic device according to any one of (1) to (5) above, further including

an underfill resin layer formed between the second main surface and the terminal surface.

(7) The electronic device according to any one of (1) to (6) above, in which

the first circuit board further includes an insulating resin film that is placed between the first main surface and the plurality of external terminals and is softer than the plurality of external terminals.

(8) The electronic device according to any one of (1) to (7) above, in which

each of the plurality of connection terminals includes a projection electrode formed of a first bonding material, and

each of the plurality of external terminals includes a projection electrode formed of a second bonding material that is the same as the first bonding material.

(9) The electronic device according to any one of (1) to (8) above, in which

the second circuit board includes a plurality of boards, the plurality of boards each including the plurality of connection terminals.

(10) The electronic device according to any one of (1) to (9) above, in which

the second circuit board is a board including a sensor unit. (11) A part mounting board, including:

a first circuit board that includes a first main surface, a second main surface, and a plurality of external terminals arranged on the first main surface in a matrix pattern, the plurality of external terminals including a first terminal group located at an outermost periphery of the first main surface;

a second circuit board that includes a terminal surface facing the second main surface, and a plurality of connection terminals electrically connected to the second main surface, the plurality of connection terminals including a second terminal group that is arranged on the terminal surface and faces at least a part of the first terminal group; and

a third board that is arranged so as to face the first main surface and electrically connected to the plurality of external terminals.

(12) An electronic apparatus, including:

a first circuit board that includes a first main surface, a second main surface, and a plurality of external terminals arranged on the first main surface in a matrix pattern, the plurality of external terminals including a first terminal group located at an outermost periphery of the first main surface;

a second circuit board that includes a terminal surface facing the second main surface, and a plurality of connection terminals electrically connected to the second main surface, the plurality of connection terminals including a second terminal group that is arranged on the terminal surface and faces at least a part of the first terminal group; and

a third board that is arranged so as to face the first main surface and electrically connected to the plurality of external terminals.

### REFERENCE SIGNS LIST

1,2 electronic device

10 first circuit board

11board body

12 ex ternal terminal

12A,12B terminal group

12C dummy terminal

13 pad portion

14 resin film

20 second circuit board

21 board body

22 connection terminal

22C dummy terminal

30 mounting board

41,42 underfill resin layer

100,300,400,500,600 part mounting board

111 first main surface

112 second main surface

120,220 projection electrode

201,202 second circuit board

211 terminal surface

1. An electronic device, comprising:
a first circuit board that includes a first main surface, a second main surface, and a plurality of external terminals arranged on the first main surface in a matrix pattern, the plurality of external terminals including a first terminal group located at an outermost periphery of the first main surface; and
a second circuit board that includes a terminal surface facing the second main surface, and a plurality of connection terminals electrically connected to the second main surface, the plurality of connection terminals including a second terminal group that is arranged on the terminal surface and faces at least a part of the first terminal group.

2. The electronic device according to claim 1, wherein
a part of at least one of the first terminal group and the second terminal group includes dummy terminals.

3. The electronic device according to claim 2, wherein
the first circuit board has a rectangular shape, and
the dummy terminals are arranged on four corners of at least one of the first main surface and the second main surface.

4. The electronic device according to claim 1, wherein
the first circuit board includes a semiconductor substrate.

5. The electronic device according to claim 4, wherein
the semiconductor substrate includes an integrated circuit.

6. The electronic device according to claim 1, further comprising
an underfill resin layer formed between the second main surface and the terminal surface.

7. The electronic device according to claim 1, wherein
the first circuit board further includes an insulating resin film that is placed between the first main surface and the plurality of external terminals and is softer than the plurality of external terminals.

8. The electronic device according to claim 1, wherein
each of the plurality of connection terminals includes a projection electrode formed of a first bonding material, and
each of the plurality of external terminals includes a projection electrode formed of a second bonding material that is the same as the first bonding material.

9. The electronic device according to claim 1, wherein
the second circuit board includes a plurality of boards, the plurality of boards each including the plurality of connection terminals.

10. The electronic device according to claim 1, wherein
the second circuit board is a board including a sensor unit.

11. A part mounting board, comprising:
a first circuit board that includes a first main surface, a second main surface, and a plurality of external terminals arranged on the first main surface in a matrix pattern, the plurality of external terminals including a first terminal group located at an outermost periphery of the first main surface;
a second circuit board that includes a terminal surface facing the second main surface, and a plurality of connection terminals electrically connected to the second main surface, the plurality of connection terminals including a second terminal group that is arranged on the terminal surface and faces at least a part of the first terminal group; and
a third board that is arranged so as to face the first main surface and electrically connected to the plurality of external terminals.

12. An electronic apparatus, comprising:
a first circuit board that includes a first main surface, a second main surface, and a plurality of external terminals arranged on the first main surface in a matrix pattern, the plurality of external terminals including a first terminal group located at an outermost periphery of the first main surface;
a second circuit board that includes a terminal surface facing the second main surface, and a plurality of connection terminals electrically connected to the second main surface, the plurality of connection terminals including a second terminal group that is arranged on the terminal surface and faces at least a part of the first terminal group; and
a third board that is arranged so as to face the first main surface and electrically connected to the plurality of external terminals.
